(19) United States
(12) Patent Application Publication
(10) Pub. No.: US 2025/0220777 A1
(43) Pub. Date: Jul. 3, 2025

(54) Method and Apparatus of Substrate Support Repair and Refurbishment

(71) Applicant: Applied Materials, Inc., Santa Clara, CA (US)

(72) Inventors: Ying MA, Castro Valley, CA (US); Stanley WU, Santa Clara, CA (US); Anand VASUDEV, Los Gatos, CA (US)

(21) Appl. No.: 18/397,746

(22) Filed: Dec. 27, 2023

(51) Int. Cl. H05B 3/14; C04B 41/53; H05B 3/28

(52) U.S. Cl. CPC H05B 3/143; C04B 41/53; H05B 3/283

(57) ABSTRACT

Methods of refurbishing ceramic heaters are provided herein. In some embodiments, a method of refurbishing a ceramic heater having one or more heating elements disposed therein includes: grinding off a top portion of the ceramic heater to form a ground ceramic heater having a first upper layer, wherein the ground ceramic heater includes the one or more heating elements disposed below the first upper layer; coupling a ceramic top to the first upper layer of the ground ceramic heater; and sealing one or more edge regions of an interface between the ceramic top and the ground ceramic heater to form a refurbished ceramic heater.

### FIELD

Embodiments of the present disclosure generally relate to substrate processing equipment.

### BACKGROUND

Ceramic heaters are components for use in semiconductor process chambers to help support substrates disposed thereon. Ceramic heaters also help to generate heat and maintain a desired temperature and promote temperature uniformity of the substrate. Ceramic heaters may also be an important component for RF delivery. However, ceramic heaters may form defects over time such as cracking, chipping, delamination, or changing of critical dimensions that make the ceramic heater out of spec or unusable.

Accordingly, the inventors have provided herein embodiments of methods and apparatus of repairing or refurbishing ceramic heaters.

### SUMMARY

Methods of refurbishing ceramic heaters are provided herein. In some embodiments, a method of refurbishing a ceramic heater having one or more heating elements disposed therein includes: grinding off a top portion of the ceramic heater to form a ground ceramic heater having a first upper layer, wherein the ground ceramic heater includes the one or more heating elements disposed below the first upper layer; coupling a ceramic top to the first upper layer of the ground ceramic heater; and sealing one or more edge regions of an interface between the ceramic top and the ground ceramic heater to form a refurbished ceramic heater.

In some embodiments, a method of refurbishing a ceramic heater having one or more heating elements disposed therein includes: grinding off a top portion of the ceramic heater to form a ground ceramic heater having a first upper layer, wherein the ceramic heater is an electrostatic chuck having an RF mesh disposed therein, wherein grinding the top portion includes removing the RF mesh, and wherein the ground ceramic heater includes the one or more heating elements disposed below the first upper layer; bonding a ceramic top having a new RF mesh to the first upper layer of the ground ceramic heater via a metal filler; and sealing edge regions of an interface between the ceramic top and the ground ceramic heater to seal the metal filler and to form a refurbished ceramic heater.

In some embodiments, a substrate support includes: a ground ceramic heater having one or more heating elements disposed therein; and a replacement ceramic top bonded to the ground ceramic heater, wherein an edge region of the interface between the ground ceramic heater and the replacement ceramic top is sealed.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of refurbishing a ceramic heater in accordance with at least some embodiments of the present disclosure.

FIG. 2 depicts a schematic cross-sectional side view of a ceramic heater having defects in accordance with at least some embodiments of the present disclosure.

FIG. 3 depicts a schematic cross-sectional side view of a ceramic heater after removal of an RF rod and heating element terminals in accordance with at least some embodiments of the present disclosure.

FIG. 4 depicts a schematic cross-sectional side view of a ceramic heater after grinding off a top portion of the ceramic heater in accordance with at least some embodiments of the present disclosure.

FIG. 5 depicts a schematic cross-sectional side view of a ceramic top in accordance with at least some embodiments of the present disclosure.

FIG. 6A depicts a schematic cross-sectional side view of a ceramic heater after bonding a ground ceramic heater to a ceramic top in accordance with at least some embodiments of the present disclosure.

FIG. 6B depicts a schematic cross-sectional side view of a ceramic heater after bonding a ground ceramic heater to a ceramic top in accordance with at least some embodiments of the present disclosure.

FIG. 7 depicts a schematic cross-sectional side view of a ceramic heater after forming a mesa pattern on an upper surface of a ceramic top in accordance with at least some embodiments of the present disclosure.

FIG. 8 depicts a schematic cross-sectional side view of a ceramic heater after attaching an RF rod and heating element terminals to the ground ceramic heater in accordance with at least some embodiments of the present disclosure.

FIG. 9 depicts a schematic cross-sectional side view of a ceramic heater with a non-metal foil disposed between a ceramic top and a ground ceramic heater in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Substrate supports are generally used to support a substrate to be processed. Embodiments of methods of refurbishing substrate supports, such as ceramic heaters and refurbished ceramic heaters are provided herein. The method generally includes grinding a top portion of the ceramic heater to form a ground ceramic heater and bonding a ceramic top to the ground ceramic heater to form a refurbished ceramic heater. The bonding material is advantageously selected to enable the ceramic heater to perform high temperature processes (e.g., up to about 800 degrees C.). In embodiments where the ceramic heater includes one or more chucking electrodes, the methods provided herein advantageously facilitate repairing or refurbishing defects at or below the one or more chucking electrodes. In such embodiments, the ceramic top may include replacement ones of the one or more chucking electrodes.

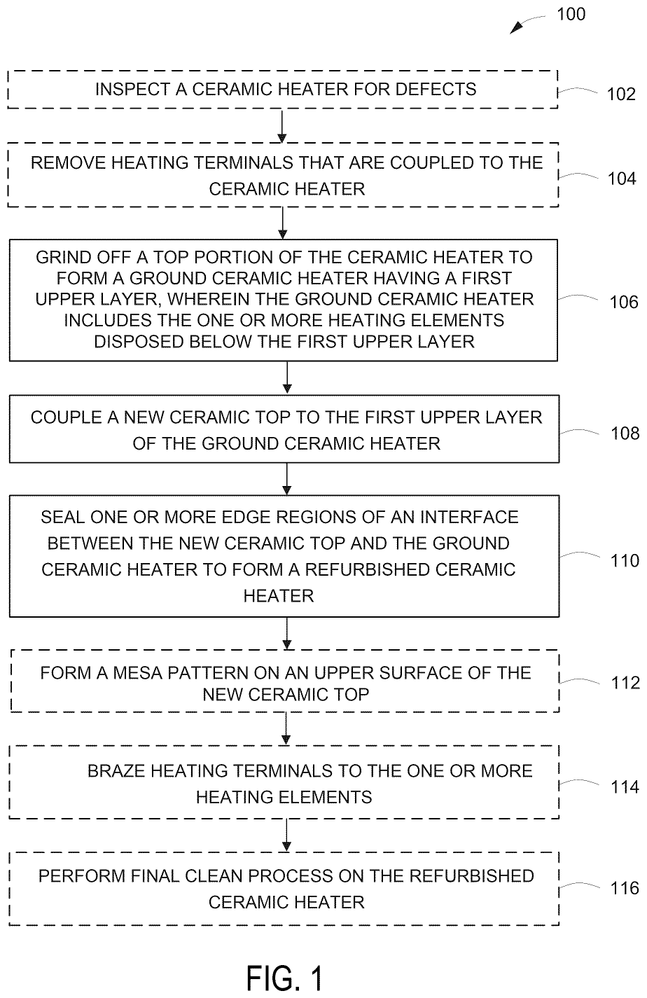

FIG. 1 depicts a flow chart of a method 100 of refurbishing a ceramic heater (e.g., ceramic heater 200) in accordance with at least some embodiments of the present disclosure. At 102, the method 100 optionally includes inspecting the ceramic heater for defects. In some embodiments, defects may include cracking, chipping, delamination, or changing of critical dimensions. Defects may arise from general wear and tear, thermal cycling, processing, or the like. The defects may be detected via visual inspection or other suitable inspection techniques such as optical inspection, e-beam inspection, IR inspection, or the like. The ceramic heater 200 may be inspected within a process chamber in which the ceramic heater 200 is installed. In some embodiments, the ceramic heater 200 may be inspected outside of the process chamber in which the ceramic heater 200 is installed. The process chamber may be any suitable chamber for semiconductor substrate processing, such as a deposition chamber, etch chamber, or the like.

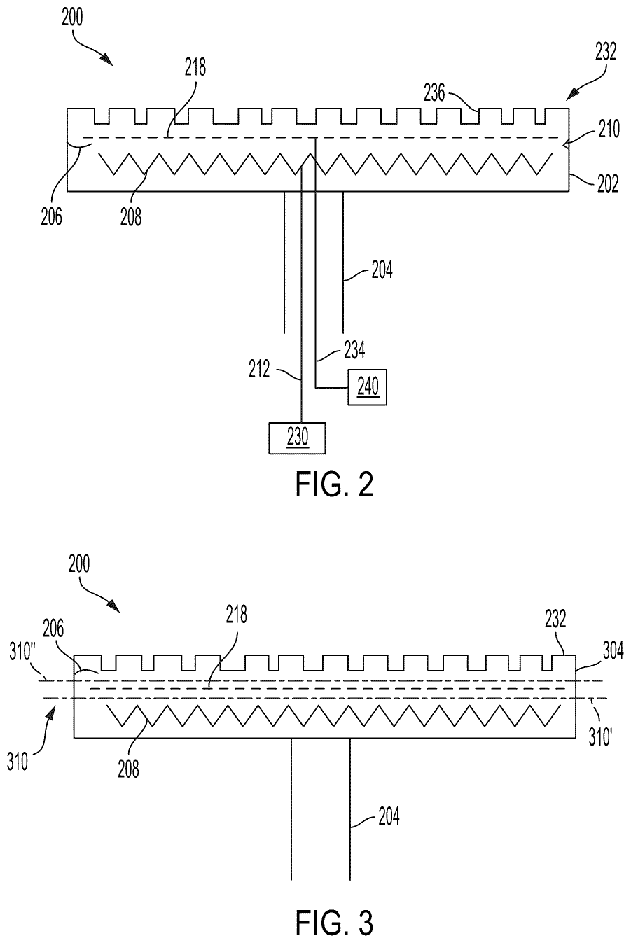

FIG. 2 depicts a schematic cross-sectional side view of a ceramic heater 200 having defects in accordance with at least some embodiments of the present disclosure. For example, the ceramic heater 200 may include defects such as one or more cracks 206. In some embodiments, the ceramic heater 200 may include defects such as one or more chipped surfaces 210. The ceramic heater 200 generally comprises a pedestal 202 coupled to a hollow shaft 204. The pedestal 202 includes one or more heating elements 208, such as resistive heating elements configured to generate heat when electricity is passed therethrough. The one or more heating elements 208 comprises a suitable metal material having a melting point of greater than about 700 degrees, such as molybdenum or a molybdenum alloy.

In some embodiments, the pedestal 202 includes one or more electrodes disposed therein to deliver RF power to the pedestal 202. The one or more electrodes may comprise an RF mesh 218. The RF mesh 218 may be configured as a chucking electrode so that the ceramic heater 200 is an electrostatic chuck. The RF mesh 218 comprises a suitable metal material having a melting point of greater than about 700 degrees, such as molybdenum or a molybdenum alloy. The RF mesh 218 may be disposed vertically above the one or more heating elements 208.

The hollow shaft 204 may provide a conduit for various connections to the pedestal 202, such as electrical lines or terminals for the ceramic heater 200, backside gas lines, or the like. For example, heating element terminals 212 may extend through the hollow shaft 204 to couple power from a heater power source 230 to the one or more heating elements 208. In some embodiments, an RF rod 234 may extend through the hollow shaft 204 to couple power from an RF power source 240 to the RF mesh 218. The RF rod 234 may be made of a suitable metal, such as nickel or a nickel alloy. An upper surface 232 of the ceramic heater 200 may include a plurality of mesas 236 arranged in a mesa pattern suitable for reducing a contact area between the pedestal 202 and a substrate when disposed on the pedestal 202.

Returning back to FIG. 1, the method 100, at 104, may optionally include removing heating element terminals (e.g., heating element terminals 212) that are coupled to the one or more heating elements 208 in the pedestal 202. In some embodiments, the method 100 includes removing the RF rod 234 from the pedestal 202. The method 100 may generally include removing any connections to a lower surface of the ceramic heater 200. FIG. 3 depicts a schematic cross-sectional side view of a ceramic heater 200 after removal of the RF rod 234 and the heating element terminals 212 in accordance with at least some embodiments of the present disclosure. In some embodiments, the ceramic heater 200 includes a top portion 304 disposed above a separation line 310. The top portion 304 is generally disposed above the one or more heating elements 208. In some embodiments, the separation line 310 is disposed between the one or more heating elements 208 and the RF mesh 218 (as indicated by separation line 310′). In some embodiments, the separation line 310 is disposed above the RF mesh 218 (as indicated by separation line 310″).

At 106, the method 100 includes grinding off a top portion (e.g., top portion 304) of the ceramic heater to form a ground ceramic heater (e.g., ground ceramic heater 410) having a first upper layer (e.g., first upper layer 414). Grinding may comprise any suitable grinding process such as lapping, honing, mechanical grinding, or the like. In some embodiments, grinding the top portion includes removing the RF mesh 218, for example along the separation line 310′. In some embodiments, grinding the top portion may not include removing the RF mesh 218, for example along separation line 310″. For example, the RF mesh 218 may be grinded off if the RF mesh 218 is location in a shallow region in the ceramic heater 200 and not grinded off if in a deep location in the ceramic heater 200.

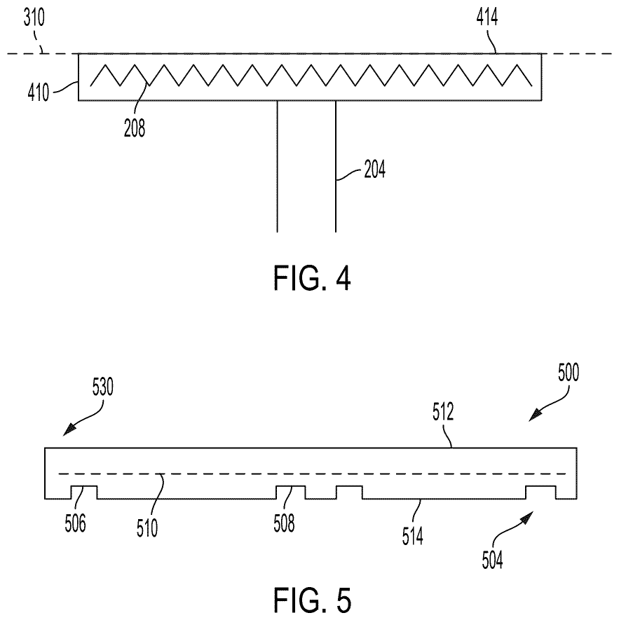

FIG. 4 depicts a schematic cross-sectional side view of a ceramic heater 200 after grinding off the top portion 304 in accordance with at least some embodiments of the present disclosure. FIG. 4 depicts an example of ground ceramic heater 410 that is grinded to the separation line 310′ (with the RF mesh 218 removed). In some embodiments, grinding the top portion 304 includes removing some ceramic material disposed below the RF mesh 218 in the ceramic heater 200. In some embodiments, the ground ceramic heater 410 includes the one or more heating elements 208 disposed below the first upper layer 414.

At 108, the method 100 includes coupling a ceramic top to the first upper layer of the ground ceramic heater. In some embodiments, if the ground ceramic heater does not have the RF mesh, the ceramic top has a new RF mesh. In some embodiments, the ceramic top is coupled to the ground ceramic heater via a metal filler (e.g., metal filler 602). Bonding via the metal filler is performed in a central region of the ceramic top and not in edge regions of the ceramic top. For example, the metal filler is generally disposed in a central region between the ceramic top and the ground ceramic heater so that the metal filler does not overflow to edge regions (e.g., edge regions 530) of the ceramic top. In some embodiments, the metal filler comprises a copper or silver alloy. In some embodiments, the metal filler forms a layer about 0.02 mm to about 0.2 mm thick.

FIG. 5 depicts a schematic cross-sectional side view of a ceramic top 500 in accordance with at least some embodiments of the present disclosure. The ceramic top 500 includes an upper surface 512 and a lower surface 514 opposite the upper surface 512. The ceramic top 500 may be a replacement ceramic top, such as a new ceramic top or a refurbished ceramic top. In some embodiments, the ceramic top 500 includes a new RF mesh 510. In some embodiments, the ceramic top 500 includes one or more notches 504 disposed along the lower surface 514 to advantageously reduce or prevent metal filler from overflowing to edge regions 530 of the ceramic top 500. For example, the one or more notches 504 may include an inner annular notch 508. In some embodiments, the one or more notches 504 may include an outer annular notch 506. In some embodiments, the edge regions 530 are disposed radially outward of the one or more notches 504. In some embodiments, the outer annular notch 506 is larger in width, depth, or width and depth than the inner annular notch 508. The smaller inner annular notch 508 may advantageously prevent the metal filler from flowing onto an electrical connector, for example, an RF connector at a center of the ceramic top 500. The larger outer annular notch 506 may prevent the metal filler from leaking out from the edge regions 530 or from an outer edge of an interface between the ceramic top 500 and the ground ceramic heater 410.

In some embodiments, the ground ceramic heater 410 may be machined to include one or more notches, instead of the ceramic top 500 having the one or more notches 504, to reduce or prevent the metal filler from overflowing to edge regions 530 of the ceramic top 500. In some embodiments, both the ground ceramic heater 410 and the ceramic top 500 may include one or more notches at corresponding locations. In some embodiments, the ceramic top 500 is coupled to the ground ceramic heater 410 via diffusion bonding, such as ceramic diffusion bonding, at edge regions and middle regions of the interface between the ceramic top 500 and the ground ceramic heater 410. In some embodiments, the ceramic top 500 is unbonded with the ground ceramic heater 410 at a central region of the interface therebetween due to interference of the hollow shaft 204 and diffusion bonded at edge regions and the middle regions of the interface therebetween. The middle regions of the interface between the ceramic top 500 and the ground ceramic heater 410 are disposed between the central region and the edge region.

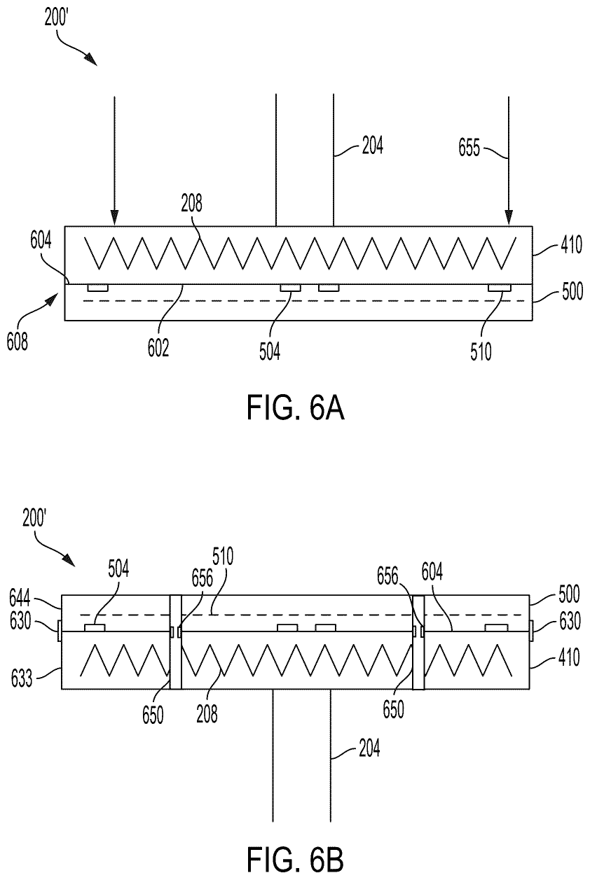

At 110, the method 100 includes sealing one or more edge regions (e.g., edge regions 604) of an interface (e.g., interface 608) between the ceramic top and the first upper layer of the ground ceramic heater to seal the metal filler and to form a refurbished ceramic heater 200′. In some embodiments, as depicted in FIG. 6A, sealing the edge regions 604 of the interface 608 comprises diffusion bonding the edge regions 604 of the ceramic top 500 to edge regions of the first upper layer 414. The diffusion bonding may be performed with an external force 655 on a circumferential edge of the ground ceramic heater 410 to bond the two pieces of ceramic together. The diffusion bonding advantageously seals the interface and prevents the metal filler from being exposed to vacuum during processing and causing potential contamination issues.

In some embodiments, when diffusion bonding is deployed to seal the edge regions 604, as discussed above, the central region may remain unbonded and the sealing process also couples the ground ceramic heater to the ceramic top. In some embodiments, sealing the one or more edge regions of the interface includes applying a plasma spray coating 630, as depicted in FIG. 6B, along the interface 608 between the ceramic top 500 and the ground ceramic heater 410 to seal the metal filler. In some embodiments, the plasma spray coating 630 coats a layer on outer sidewalls 633 of the ground ceramic heater 410 and outer sidewalls 644 of the ceramic top 500 at the interface 608 to advantageously seal the interface 608 and prevent the metal filler 602 from being exposed to vacuum and contaminating a process chamber. In some embodiments, the ceramic heater 200′ includes through features disposed therethrough, for example, lift pin openings 650. In some embodiments, the interface between the ceramic top 500 and the ceramic heater 410 is sealed at the lift pin openings 650, for example, via diffusion bonding or plasma spray coating 656. In some embodiments, the lift pin openings 650 are disposed radially between the inner annular notch 508 and the outer annular notch 506.

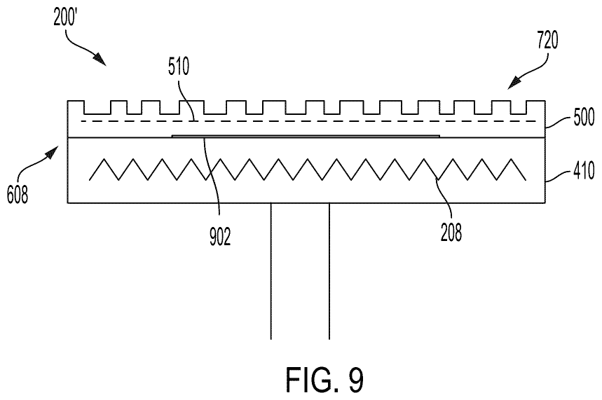

In some embodiments, the method 100 includes placing a non-metal foil (e.g., non-metal foil 902) between the ceramic top and the ground ceramic heater prior to sealing the edge regions. FIG. 9 depicts a schematic cross-sectional side view of a ceramic heater 200′ with a non-metal foil 902 disposed between a ceramic top 500 and a ground ceramic heater 410 in accordance with at least some embodiments of the present disclosure. The non-metal foil 902 can be, for example, a graphite foil. The non-metal foil 902 may not be for bonding but for facilitating enhanced heat transfer between the ground ceramic heater 410 and the ceramic top 500. In some embodiments, the method 100 includes placing the non-metal foil 902 between the ceramic top 500 and the ground ceramic heater 410 in a central region of the interface 608 and then coupling the edge regions of the interface 608 via a diffusion bonding process. In some embodiments, the method 100 includes applying the plasma spray coating 630 after coupling the edge regions via the diffusion bonding process.

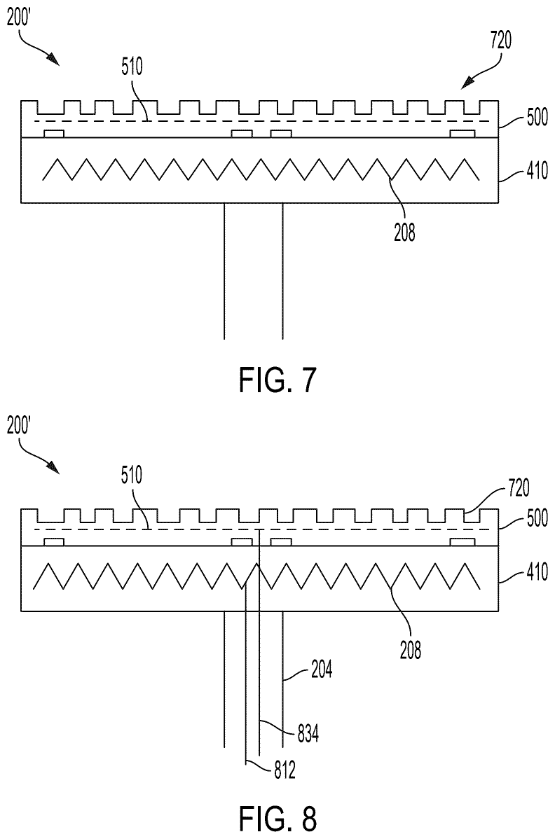

At 112, the method 100 optionally includes forming a mesa pattern on an upper surface of the ceramic top. FIG. 7 depicts a schematic cross-sectional side view of a refurbished ceramic heater 200′ after forming a mesa pattern 720 on an upper surface 512 of a ceramic top 500 in accordance with at least some embodiments of the present disclosure.

At 114, the method 100 optionally includes brazing heating element terminals (e.g., heating element terminals 812) to the one or more heating elements disposed in the ground ceramic heater. In some embodiments, the method 100 includes attaching an RF rod (e.g., RF rod 834) to the ground ceramic heater. FIG. 8 depicts a schematic cross-sectional side view of a ceramic heater 200 after attaching the RF rod 834 and heating element terminals 812 to the ground ceramic heater 410 in accordance with at least some embodiments of the present disclosure. In some embodiments, the RF rod 834 is the RF rod 234. In some embodiments, the heating element terminals 812 are the heating element terminals 212.

In some embodiments, the method 100 at 116 optionally includes performing a final clean process on the refurbished ceramic heater 200′ after bonding the ceramic top 500 to the ground ceramic heater 410. The cleaning process may comprise any suitable cleaning process to remove any contaminants or unwanted particles from the refurbished ceramic heater 200′. In some embodiments, the method 100 includes performing an outgoing inspection after the final clean. In some embodiments, the

While the foregoing is directed to embodiments of the present disclosure, other and further embodiments of the disclosure may be devised without departing from the basic scope thereof.

1. A method of refurbishing a ceramic heater having one or more heating elements disposed therein, comprising:
grinding off a top portion of the ceramic heater to form a ground ceramic heater having a first upper layer, wherein the ground ceramic heater includes the one or more heating elements disposed below the first upper layer;
coupling a ceramic top to the first upper layer of the ground ceramic heater; and
sealing one or more edge regions of an interface between the ceramic top and the ground ceramic heater to form a refurbished ceramic heater.

2. The method of claim 1, wherein coupling the ceramic top to the first upper layer comprises bonding the ceramic top to the first upper layer via a metal filler.

3. The method of claim 2, wherein the ceramic top or ground ceramic heater includes one or more notches to reduce or prevent the metal filler from overflowing to one or more edge regions of the ceramic top.

4. The method of claim 3, wherein the one or more notches includes an outer annular notch and an inner annular notch, wherein the outer annular notch is larger than the inner annular notch.

5. The method of claim 1, wherein the ceramic heater includes one or more lift pin openings, and further comprising sealing the one or more lift pin openings at the interface between the ceramic top and the ceramic heater.

6. The method of claim 5, wherein the ceramic heater includes an RF mesh and grinding the top portion includes removing the RF mesh and some ceramic material disposed below the RF mesh.

7. The method of claim 1, wherein coupling the ceramic top to the first upper layer and sealing the one or more edge regions of the interface between the ceramic top and the ground ceramic heater comprises diffusion bonding the one or more edge regions of the interface.

8. The method of claim 1, wherein sealing the one or more edge regions of the interface comprises at least one of:
diffusion bonding one or more edge regions of the ceramic top to one or more edge regions of the first upper layer; or
applying a plasma spray coating along the interface between the ceramic top and the ground ceramic heater.

9. The method of claim 1, further comprising placing a non-metal foil between the ceramic top and the ground ceramic heater prior to sealing the one or more edge regions.

10. A method of refurbishing a ceramic heater having one or more heating elements disposed therein, comprising:
grinding off a top portion of the ceramic heater to form a ground ceramic heater having a first upper layer, wherein the ceramic heater is an electrostatic chuck having an RF mesh disposed therein, wherein grinding the top portion includes removing the RF mesh, and wherein the ground ceramic heater includes the one or more heating elements disposed below the first upper layer;
bonding a ceramic top having a new RF mesh to the first upper layer of the ground ceramic heater via a metal filler; and
sealing edge regions of an interface between the ceramic top and the ground ceramic heater to seal the metal filler and to form a refurbished ceramic heater.

11. A substrate support, comprising:
a ground ceramic heater having one or more heating elements disposed therein; and
a replacement ceramic top bonded to the ground ceramic heater, wherein an edge region of an interface between the ground ceramic heater and the replacement ceramic top is sealed.

12. The substrate support of claim 11, wherein a lower surface of the replacement ceramic top or upper surface of the ground ceramic heater includes one or more notches configured to receive overflow of a metal filler disposed between the ground ceramic heater and the replacement ceramic top.

13. The substrate support of claim 12, wherein the one or more notches includes an outer annular notch and an inner annular notch, wherein the outer annular notch is larger in width or depth than the inner annular notch.

14. The substrate support of claim 11, wherein the edge region is sealed via plasma spray coating and the plasma spray coating is disposed along outer sidewalls of the replacement ceramic top and the ground ceramic heater.

15. The substrate support of claim 11, further comprising a metal filler disposed in a central region of an interface between the ground ceramic heater and the replacement ceramic top, and wherein the interface is sealed to prevent the metal filler from being exposed at an outer edge of the interface between the ground ceramic heater and the replacement ceramic top.

16. The substrate support of claim 15, wherein the metal filler comprises a copper or silver alloy.

17. The substrate support of claim 11, further comprising an RF mesh disposed in the ceramic top.

18. The substrate support of claim 11, further comprising a non-metal foil disposed between the ground ceramic heater and the replacement ceramic top.

19. The substrate support of claim 11, wherein the replacement ceramic top includes a plurality of mesas on an upper surface thereof.

20. The substrate support of claim 11, wherein the replacement ceramic top includes lift pin openings.
